(19) United States
(12) Patent Application Publication
(10) Pub. No.: US 2006/0160371 A1
(43) Pub. Date: Jul. 20, 2006

(54) Inhibiting growth under high dielectric constant films

(76) Inventors: Matthew V. Metz, Hillsboro, OR (US); Suman Datta, Beaverton, OR (US); Jack Kavalieros, Portland, OR (US); Mark L. Doczy, Beaverton, OR (US); Justin K. Brask, Portland, OR (US); Robert S. Chau, Beaverton, OR (US)

Correspondence Address: TROP PRUNER & HU, PC, 8554 KATY FREEWAY, SUITE 100, HOUSTON, TX, 77024, US

(21) Appl. No.: 11/037,644

(22) Filed: Jan. 18, 2005

(51) Int. Cl. H01L 21/31

(52) U.S. Cl. 438/761; 438/778; 438/791

(57) ABSTRACT

Oxidation between a higher dielectric constant material such as a rare earth oxide and a substrate may be reduced by providing a seal layer over the gate dielectric. In some embodiments, the seal layer may be isolated from the gate dielectric by a buffer layer.

### BACKGROUND

This invention relates generally to the fabrication of MOS field effect transistors.

As transistors are continuing to scale or become smaller in size, gate leakage is becoming unacceptably high. Using smaller transistors means more complex operations can be done by lower cost devices.

One way to continue gate scaling while maintaining acceptable leakage is to use gate dielectrics with higher dielectric constants. As used herein, a higher gate dielectric constant is a dielectric constant of greater than 10. One type of higher gate dielectric constant materials is the rare earth dielectrics, including lanthanum oxide.

Some higher gate dielectric constant materials, particularly including the rare earth oxides, are prone to forming silica or silicate layers between the substrate and the higher dielectric constant films. This is because some higher dielectric constant gate dielectrics allow diffusion of oxygen through the film. This diffusion allows a silicon dioxide or silicate layer to grow between the substrate and the gate dielectric. This extra dielectric layer increases electrical thickness, and degrades capacitance and transistor performance.

Thus, there is a need for better ways to form transistors.

### BRIEF DESCRIPTION OF THE DRAWINGS

FIG. 1 is an enlarged, cross-sectional view at an early stage of manufacture in accordance with one embodiment of the present invention;

FIG. 2 is an enlarged, cross-sectional view at a subsequent state of manufacture in accordance with one embodiment of the present invention;

FIG. 3 is an enlarged, cross-sectional view at a subsequent state of manufacture in accordance with one embodiment of the present invention; and

FIG. 4 is an enlarged, cross-sectional view at a subsequent state of manufacture in accordance with one embodiment of the present invention.

### DETAILED DESCRIPTION

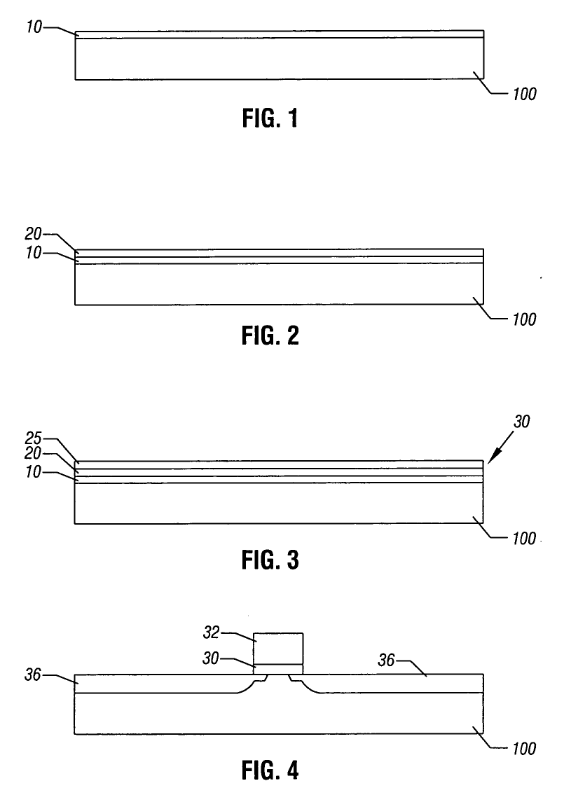

Referring to FIG. 1, a semiconductor substrate 100 may have a higher dielectric constant gate dielectric 10 formed thereon. The substrate 100 may be formed, for example, of silicon or any suitable material from groups III through IV of the periodic table. The substrate 100 may be prepared for higher dielectric constant dielectric deposition by a pre-clean step.

Examples of suitable higher dielectric constant gate dielectrics include the rare earth oxides such as oxides of lanthanum, yttrium, scandium, dysprosium, gadolinium, lutetium, and samarium.

The gate dielectric 10 may be deposited using atomic layer deposition. A heated deposition chamber may be supplied with a first precursor contained in liquid form within a closed, pressurized, heated, reservoir. The liquid in that reservoir is heated by a heater to form a vapor. The injection of the first precursor as a vapor into the chamber may be controlled by a high speed valve. In one embodiment, the precursor may be an oxidant such as water, hydrogen peroxide, or ozone.

A metal precursor may be stored in another closed, pressurized, heated, reservoir. The metal precursor, for example, may include a rare earth metal in one embodiment. The reservoir communicates with the chamber via a high speed valve. The metal precursor may be a liquid that is converted to a vapor by a heater.

In a pre-stabilization stage, the wafers are loaded into the chamber. Then, that chamber may be heated to a desired temperature. The heaters associated with the reservoirs may also be activated to ramp the reservoirs to target temperatures.

After the pre-stabilization stage, the metal precursor is vaporized and injected as a pulse into the chamber. The pulse length is set by a high speed valve. The metal precursor pulse may be followed by a purge cycle. In the purge cycle, the metal precursor gas that was previously applied is exhausted using a neutral gas such as nitrogen in a vacuum pump. The duration of the pulse and purge may be controlled as desired to achieve particular film thicknesses in particular situations.

After the purging of the metal precursor, a pulse of oxidant, such as water, may be applied from its reservoir, followed by purging of the oxidant. This sequence of four pulses in a specified order may be repeated to achieve a desired film thickness formed of monolayers built up by each pulse. A monolayer is a layer of material having a thickness of one molecule. In one embodiment, the sequence may be repeated three or four times. However, in other cases, the pulses are simply repeated until the desired thickness is achieved.

In one embodiment, the chamber reaches a temperature of approximately 200 to 400 degrees during the pre-stabilization period. The temperature of the metal precursor may be from about 150 to about 25° C. The temperature of the silicon precursor may be from about 10 to about 40° C. The temperature of the oxidant may be from about 10 to about 40° C. The temperature in the chamber may be from about 200 to about 400° C. in one embodiment.

In some embodiments, after the higher dielectric constant gate dielectric 10 has been deposited, a buffer layer 20 may be formed as shown in FIG. 2. The buffer layer may be formed by atomic layer deposition (ALD), plasma enhanced (PE) ALD, chemical vapor deposition (CVD), PE-CVD, or sputtering, to mention a few examples, to a thickness of from about 3 to about 2,000 Angstroms. Examples of suitable buffer layers include silicon nitride, metal, metal nitride, or metal carbide, to mention a few examples. The buffer layer may function to isolate, in some embodiments, the gate dielectric 10 from a hermetic seal layer to be subsequently applied.

Referring to FIG. 3, the hermetic seal layer 25 may be formed over the buffer layer 20 when the buffer layer 20 is utilized. The hermetic seal layer may be formed of silicon nitride, polysilicon, metal, metal nitride, or metal carbide, to mention a few examples. It functions to prevent the diffusion of oxygen through the dielectric layer 10 to form oxides between the dielectric layer 10 and the substrate 100. In one embodiment, the hermetic seal layer 25 may be deposited by atomic layer deposition (ALD), plasma enhanced (PE) ALD, chemical vapor deposition (CVD), PE-CVD, or sputtering, to mention a few examples. It may have a thickness of between about 3 and 2,000 Angstroms.

Referring finally to FIG. 4, in one embodiment of the present invention, the finished device may have a patterned gate electrode 32 over the patterned gate dielectric 30 formed of the layers 10, 20, and 25. The patterned gate electrode 32 and gate dielectric 30 may be used as a mask to form sources and drains 36. The gate electrode 32 may be polysilicon, a silicide, or a metal.

Examples of n-type metals for an n-type metal gate transistor gate electrode 32 include zirconium, hafnium, titanium, tantalum, aluminum, and their alloys including metal carbides that include these elements, such as hafnium carbide, zirconium carbide, titanium carbide, tantalum carbide, and aluminum carbide.

Examples of p-type metals for forming a p-type metal gate electrode 32 over the dielectric 30 include ruthenium, palladium, platinum, cobalt, nickel, and conductive metal oxides, including ruthenium oxide.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a seal layer under a gate electrode to prevent oxidation beneath a higher dielectric constant gate dielectric material.

2. The method of claim 1 including forming a pair of layers over said gate dielectric material including a buffer layer and said seal layer.

3. The method of claim 2 including forming said buffer layer between said seal layer and said dielectric material.

4. The method of claim 2 including forming said buffer layer of a thickness of about 3 to about 2,000 Angstroms.

5. The method of claim 4 including forming said buffer layer of a material to isolate the gate dielectric material from the seal layer.

6. The method of claim 5 including forming said buffer layer of a material selected from the group including silicon nitride, metal, metal nitride, or metal carbide.

7. The method of claim 1 including preventing the diffusion of oxygen through the higher dielectric constant gate dielectric material by forming said seal layer over said higher dielectric constant gate dielectric material.

8. The method of claim 1 including forming said seal layer of a thickness between about 3 and about 2,000 Angstroms.

9. The method of claim 8 including forming said seal layer of a material selected from the group of silicon nitride, polysilicon, metal, metal nitride, and metal carbide.

10. The method of claim 1 including forming said gate dielectric material of a rare earth oxide.

11. A semiconductor structure comprising:
a substrate;
a higher dielectric constant gate dielectric material over said substrate; and
a seal layer over said gate dielectric material to prevent oxidation of said substrate at said higher dielectric constant gate dielectric.

12. The structure of claim 11 including a buffer layer and a seal layer over said dielectric material.

13. The structure of claim 12 wherein said buffer layer is between said seal layer and said dielectric material.

14. The structure of claim 12 wherein said buffer layer is of a thickness between about 3 and about 2,000 Angstroms.

15. The structure of claim 14 wherein said buffer layer to isolate the gate dielectric material from the seal layer.

16. The structure of claim 15 wherein said buffer layer is formed of a material selected from the group including silicon nitride, metal, metal nitride, or metal carbide.

17. The structure of claim 11 including said seal layer to prevent diffusion of oxygen through the higher dielectric constant gate dielectric material.

18. The structure of claim 11 wherein said seal layer has a thickness between about 3 and about 2,000 Angstroms.

19. The structure of claim 18 wherein said seal layer is formed of a material selected from the group of silicon nitride, polysilicon, metal, metal nitride, and metal carbide.

20. The structure of claim 11 wherein said dielectric material has a rare earth oxide.

21. A method comprising:
applying a gate dielectric material to a substrate;
preventing oxidation of said substrate between said gate dielectric material and said substrate by sealing the upper surface of said gate dielectric material.

22. The method of claim 21 including providing a layer over said gate dielectric, said layer being less transmissive of oxygen than said gate dielectric layer.

23. The method of claim 22 including forming a buffer layer and a seal layer over said gate dielectric material.

24. The method of claim 23 including using said buffer layer to isolate said seal layer from said gate dielectric material.

25. The method of claim 21 wherein said dielectric material has a dielectric constant greater than 10.

26. The method of claim 21 including applying a gate dielectric material that includes a rare earth oxide.
